(19) United States
(12) Patent Application Publication
(10) Pub. No.: US 2019/0204699 A1
(43) Pub. Date: Jul. 4, 2019

(54) LIQUID CRYSTAL DISPLAY

(71) Applicant: SHENZHEN CHINA STAR OPTOELECTRONICS SEMICONDUCTOR DISPLAY TECHNOLOGY CO., LTD., Shenzhen (CN)

(72) Inventor: Wenying LI, Shenzhen (CN)

(21) Appl. No.: 15/951,878

(22) Filed: Apr. 12, 2018

Related U.S. Application Data
(63) Continuation of application No. PCT/CN2018/074596, filed on Jan. 30, 2018.

(30) Foreign Application Priority Data
Dec. 29, 2017 (CN) 201711489091.X

(51) Int. Cl. G02F 1/1362; G02F 1/1335; G02F 1/1368; G02F 1/133; H01L 27/12; G09G 3/36

(52) U.S. Cl. CPC G02F 1/136286; G02F 1/133602; G02F 1/1368; G02F 2201/123; H01L 27/124; G09G 3/3674; G09G 3/3685; G02F 1/13306

(57) ABSTRACT

The present application provides a liquid crystal display including a liquid crystal panel and a backlight module. The liquid crystal panel includes a controller, a substrate, a plurality of scan lines disposed on the substrate, a plurality of data lines, and a plurality of liquid crystal cells, each of the liquid crystal cells is electrically connected to one of the scan lines and one of the data lines simultaneously, the backlight module sequentially emits three primary colors of light in each clock cycle, the controller controls the liquid crystal cells to selectively turn on according to a target color to be displayed by each of the liquid crystal cells to transmit a predetermined amount of light of a predetermined color for visually synthesizing a target color. Thereby the filter layer is omitted, the transmittance is high, the pixel area is large, and the aperture ratio is high.

### RELATED APPLICATIONS

This application is a continuation application of POT Patent Application No. PCT/CN2018/074596, filed Jan. 30, 2018, which claims the priority benefit of Chinese Patent Application No. CN 201711489091.X, filed Dec. 29, 2017, which is herein incorporated by reference in its entirety.

### FIELD OF THE DISCLOSURE

The present disclosure relates to a panel, and more particularly to a liquid crystal display.

### BACKGROUND OF THE DISCLOSURE

Liquid crystal display with its high display quality, low prices, easy to carry, etc., to become mobile communications devices, personal computers, TVs and other display terminals. The existing liquid crystal display, each pixel consists of three sub-pixels of red, green and blue. The kind of display uses a white backlight, filtered by the filter layer to form three colors of red, green and blue to display various images. However, such a display needs three data lines for each pixel, which has high cost and requires filter layer filtering. The liquid crystal transmittance is high, the area of each sub-pixel is small, and the aperture ratio of the pixel is low.

### SUMMARY OF THE DISCLOSURE

The present application provides a liquid crystal display, which can reduce the cost, improve the transmittance and increase the aperture ratio so as to solve the above problems.

The present application provides a liquid crystal display including a liquid crystal panel and a backlight module. The liquid crystal panel includes a controller, a substrate, a plurality of scan lines disposed on the substrate, a plurality of data lines, and a plurality of liquid crystal cells, each of the liquid crystal cells is electrically connected to one of the scan lines and one of the data lines simultaneously, the backlight module sequentially emits three primary colors of light in each clock cycle, the controller controls the liquid crystal cells to selectively turn on according to a target color to be displayed by each of the liquid crystal cells to transmit a predetermined amount of light of a predetermined color for visually synthesizing a target color that the liquid crystal cells needs to display.

Preferably, the backlight module includes a three-primary-color laser source and a driving module, and the driving module drives the three-primary-color laser source to sequentially emit the three primary colors of light in each clock cycle.

Preferably, each clock cycle is divided into three equal lengths to form the one-third cycle, the two-third cycle and the three-third cycle, the three-primary-color laser source includes a red laser, a green laser and a blue laser, the driving module controls the red laser to emit red light of the three primary colors of light during the one-third cycle, controls the green laser to emit green light of the three primary colors of light during the third two-second period, and controls the blue laser to emit blue light of the three primary colors of light during the three-third cycle.

Preferably, the controller determines a transmission amount of each of the three primary colors of light necessary for synthesizing the target color before controlling the liquid crystal cells to be turned on.

Preferably, the controller respectively converts the transmission amount of each of the three primary colors of light necessary for synthesizing the target color into a corresponding transmission time, and controls the liquid crystal cells to continue being in a turn-on state the corresponding transmission times in an opened state when the backlight module emits the three primary colors of light.

Preferably, the controller controls a voltage applied to the liquid crystal cells to control a turn-on degree of the liquid crystal cells to control the brightness of the target color transmitted by the liquid crystal cells.

Preferably, the scan lines are n rows, the data lines are m columns, the liquid crystal cells are n rows and m columns, each row of the scan lines is connected to the liquid crystal cells of the corresponding row for outputting a scan signal to gate the liquid crystal cells of the corresponding row, each column of data lines is connected to the liquid crystal cells of the corresponding column for applying a driving voltage after the liquid crystal cells are gated.

Preferably, the scan lines are n/2 rows, the data lines are 2 m columns, the liquid crystal cells are n rows and m columns, each row of the scan lines is connected to corresponding two rows of liquid crystal cells for outputting a scan signal and gating the corresponding two rows of liquid crystal cells, each odd-numbered column of data lines is connected to liquid crystal cells corresponding to odd-numbered rows, and each even-numbered column of data lines is connected to liquid crystal cells of the corresponding even-numbered row for applying a driving voltage after the liquid crystal cells are gated.

Preferably, each liquid crystal cell includes a TFT, a capacitor, a pixel electrode and a liquid crystal molecule unit, the gate of the TFT is electrically connected to the corresponding scan line, the drain of the TFT is electrically connected to the corresponding data line, the source of the TFT is electrically connected to one end of the corresponding capacitor, the other end of the capacitor is grounded, an end of the pixel electrode is connected in parallel with the capacitor, the other end of the pixel electrode is grounded, a plurality of the liquid crystal molecular units form a liquid crystal molecular layer, and the pixel electrode is located at one side of the liquid crystal molecular layer.

The liquid crystal display of the present application, each liquid crystal cell can selectively transmit light of different colors emitted by the backlight module to visually synthesize the target color that the liquid crystal cell needs to display without disposing three sub-liquid crystal cells of red, green and blue for each liquid crystal cell, so that the filter layer is omitted, the transmittance is high, the pixel area is large, and the aperture ratio is high.

### BRIEF DESCRIPTION OF THE DRAWINGS

To describe the technical solutions in the embodiments of the present application or in the prior art more clearly, the following briefly introduces the accompanying drawings required for describing the embodiments or the prior art. Apparently, the accompanying drawings in the following description show merely some embodiments of the present application, and a person of ordinary skill in the art may still derive other obvious modifications based on these accompanying drawings without creative efforts.

FIG. 1 is a schematic block diagram of a liquid crystal display in an embodiment of the present application.

FIG. 2 is a schematic diagram of a liquid crystal panel of the liquid crystal display in Embodiment 1 of the present application.

FIG. 3 is a schematic diagram of a driving circuit of the liquid crystal display in Embodiment 1 of the present application.

FIG. 4 is a partial cross-sectional view of the liquid crystal panel in Embodiment 1 of the present application.

FIG. 5 is a driving timing diagram of the liquid crystal display in Embodiment 1 of the present application.

FIG. 6 is a schematic diagram of a liquid crystal panel of the liquid crystal display in Embodiment 2 of the present application.

FIG. 7 is a schematic diagram of a driving circuit of the liquid crystal display in Embodiment 2 of the present application.

FIG. 8 is a driving timing diagram of the liquid crystal display in Embodiment 2 of the present application.

### DETAILED DESCRIPTION OF PREFERRED EMBODIMENTS

The technical solutions in the embodiments of the present application are clearly and completely described below with reference to the accompanying drawings in the embodiments of the present application. Apparently, the described embodiments are merely some but not all of the embodiments of the present application. All other embodiments obtained by a person of ordinary skill in the art based on the embodiments of the present application without creative efforts shall fall in the protection scope of this application.

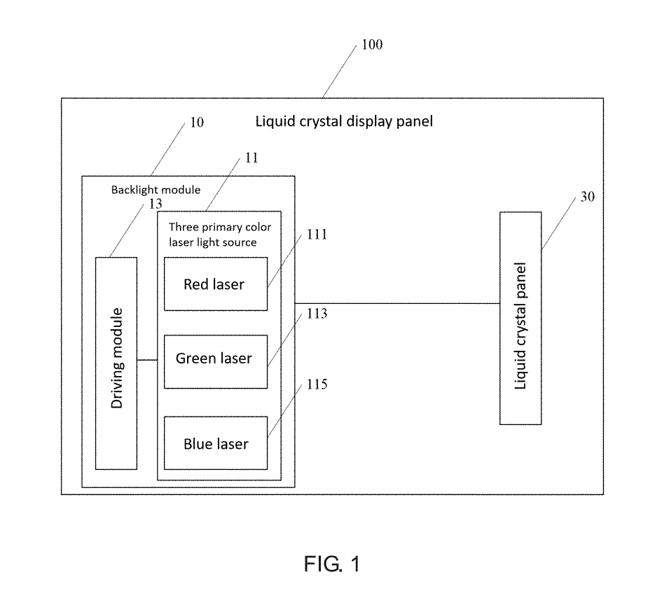

Please refer to FIG. 1, which is a block diagram of a liquid crystal display 100 in an embodiment of the present application. The liquid crystal display 100 includes a backlight module 10 and a liquid crystal panel 30. It should be understood by those skilled in the art that FIG. 1 is merely an example of the liquid crystal display 100 and does not form a limitation on the liquid crystal display 100, the liquid crystal display 100 may include more or fewer components than shown in FIG. 1 or may combine certain components or different components. For example, the liquid crystal display 100 may further includes a touch panel, a backlight, a dot-line light source conversion structure, and the like, which will not be described in detail herein because they are irrelevant to the improvement of the present application.

The backlight module 10 sequentially emits three primary colors of light in each clock cycle.

Specifically, the backlight module 10 includes a three-primary-color laser light source 11 and a driving module 13. The driving module 13 drives the three-primary-color laser sources 11 to sequentially emit three primary colors of light in each clock cycle.

More specifically, the three-primary-color laser source 11 includes a red laser 111, a green laser 113, and a blue laser 115. Each clock cycle is divided into three equal lengths to form the one-third cycle, the two-third cycle and the three-third cycle. The driving module 13 controls the red laser 111 to emit the red light of the three primary colors of light during the one-third cycle, controls the green laser 113 to emit the green light of the three primary colors of light during the two-third cycle, controls the blue laser 115 to emit the blue light of the three primary colors of light during the three-third cycle. It should be noted that, when the driving module 13 controls the red laser 111 to emit red light, the driving module 13 controls the green laser 113 and the blue laser 115 to turn off without emitting light. When the driving module 13 controls the green laser 113 to emit green light, the driving module 13 controls the red laser 111 and the blue laser 115 to turn off without emitting light. When the driving module 13 controls the blue laser 115 to emit blue light, the driving module 13 controls the red laser 111 and the green laser 113 to be turned off to emit no light. Obviously, the order of light emission in each clock cycle is not limited to the light order of red, green and blue described above, the order of light emission in each clock cycle may also be the order of blue, green and red light, as long as it ensures that the three primary colors of light are sequentially emitted in each clock cycle.

The light emitted from the backlight module 10 illuminates the liquid crystal panel 30.

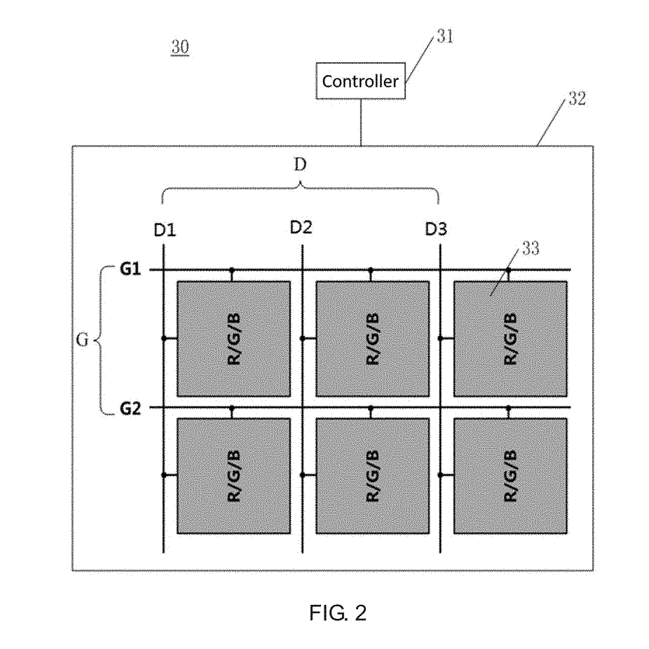

Please refer to FIG. 2. FIG. 2 is a schematic diagram of a liquid crystal panel of the liquid crystal display 100 according to Embodiment 1 of the present application. The liquid crystal panel 30 includes a controller 31, a substrate 32, a plurality of scan lines G (only two scan lines G1 and G2 are shown in the figure) disposed on the substrate 32, a plurality of data lines D (only three columns of data lines D1, D2 and D3 are shown in the figure), and a plurality of liquid crystal cells 33 (only two rows and three columns of liquid crystal cells are shown in the figure) arranged in a matrix. Each liquid crystal cell 33 is electrically connected to one of the scan lines G and one of the data lines D simultaneously. Each of the liquid crystal units 33 corresponds to a three-primary-color laser source 11 and correspondingly forms a pixel. The above-mentioned three-primary-color laser source 11 includes a plurality of three-primary-color laser sources 11 arranged in a matrix. The controller 31 controls the liquid crystal cell 33 to selectively turn on according to a target color to be displayed by each liquid crystal cell 33 so as to transmit a predetermined amount of light of a predetermined color for visually synthesizing a target color that needs to be displayed for the pixel of the liquid crystal cell 33.

Because human vision has the phenomenon of persistence of vision, that is, people's vision by the lens of the eye imaging, photoreceptor cells photosensitive and optical signals into nerve current, back to the brain to cause human visual. The photoreceptor cells rely on a number of photosensitive photographic pigment, the formation of these photographic pigments takes some time, this time is one twenty-fourth second. Therefore, as long as each liquid crystal cell is selectively turned on and transmits a predetermined amount of light of a predetermined color for less than one twenty-fourth second, a target color to be displayed for a pixel corresponding to the liquid crystal cell can be visually synthesized.

Specifically, the controller 31 determines the transmission amount of each of the three primary colors of light required to synthesize the target color before controlling the liquid crystal cell 33 to be turned on. Thus, light of various colors is synthesized depending on the amount of transmission of each color light, just as pigments of different colors are prepared on a color palette according to the amount of each pigment.

Specifically, the controller 31 respectively converts the transmission amount of each of the three primary colors of light necessary for synthesizing the target color into the corresponding transmission time, and controls the liquid crystal cell 33 corresponding to the backlight module 10 to turn on when the backlight module 10 emits the color light and continues the corresponding transmission time in the open state.

Specifically, the controller 31 controls the voltage applied to the liquid crystal cell 33 and further controls the degree of opening of the liquid crystal cell 33 to control the brightness of the target color displayed by the pixel corresponding to the liquid crystal cell 33. High voltage, high brightness, low voltage, low brightness.

Preferably, in this embodiment, the scan lines G are n rows, the data lines D are m columns, and the liquid crystal cells are n rows and m columns. Where n and m are integers greater than zero. Each row of the scan line G is connected to the liquid crystal cell 33 of the corresponding row for outputting a scan signal to gate the liquid crystal cell 33 of the corresponding row, each column of data lines is connected to a corresponding column of liquid crystal cells 33 for applying a driving voltage to the gated liquid crystal cells 33 after the liquid crystal cells 33 are turned on to control the liquid crystal cells 33 to be turned on such that the liquid crystal cells 33 transmit light.

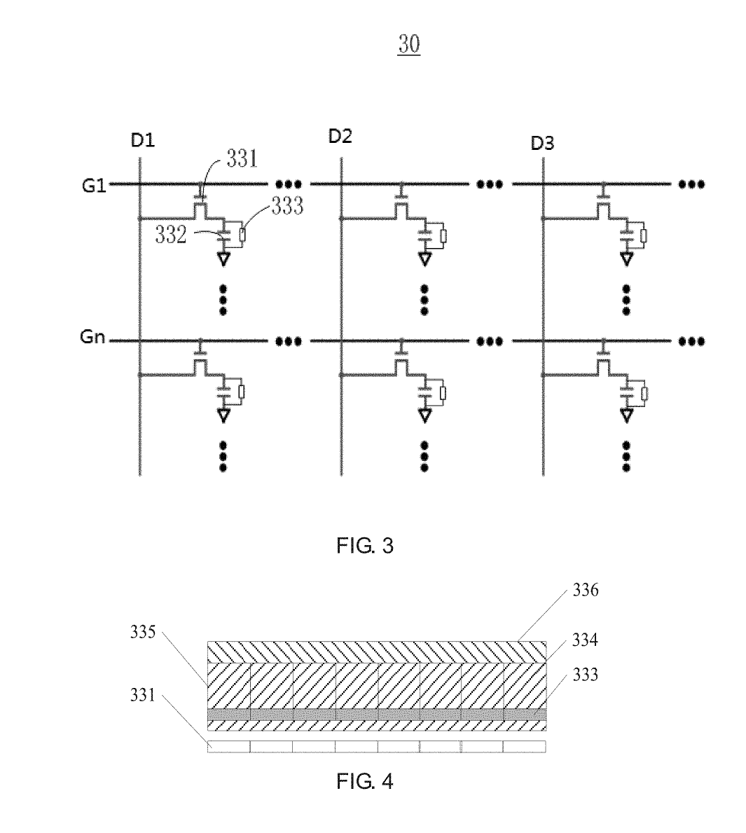

Please refer to FIG. 3 and FIG. 4 together, FIG. 3 is a schematic diagram of a driving circuit of the liquid crystal display 100 in Embodiment 1 of the present application, FIG. 4 is a partial cross-sectional view of the liquid crystal panel 30 in Embodiment 1 of the present application. Each liquid crystal cell 33 includes a TFT (Thin Film Transistor) 331, a capacitor 332, a pixel electrode 333 and a liquid crystal molecule unit 334 (not shown). The plurality of liquid crystal molecule units 334 constitute one liquid crystal molecule layer 335 shown in FIG. 4. The gate of the TFT 331 is electrically connected to the corresponding scan line G, the drain of the TFT 331 is electrically connected to the corresponding data line D, the source of the TFT 331 is electrically connected to one end of a corresponding capacitor 332, the other end of the capacitor 332 is grounded, one end of the pixel electrode 333 is connected in parallel with the capacitor 332, the other end of the pixel electrode 333 is grounded, the pixel electrode 333 and the common electrode 336 are respectively located at two sides of the liquid crystal molecule layer 335.

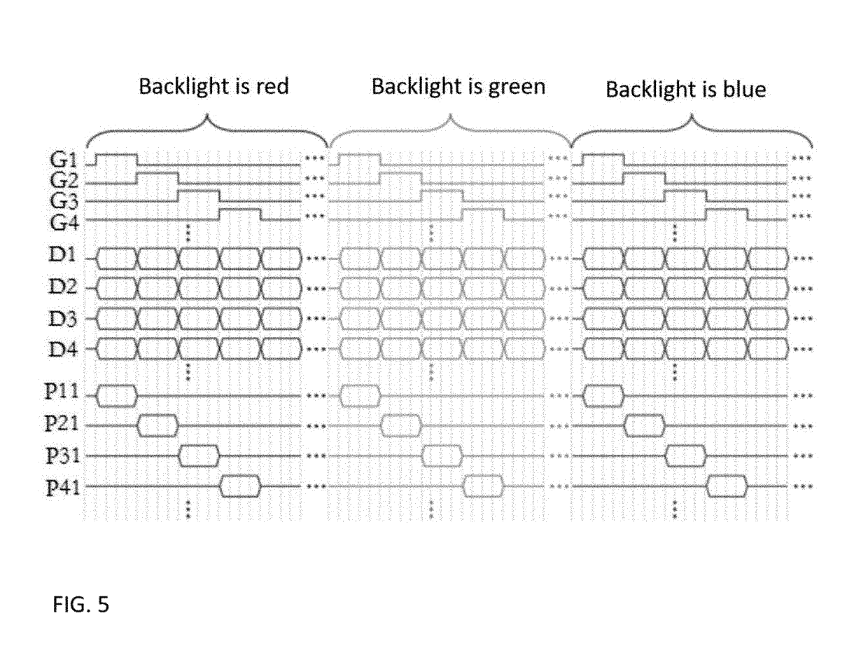

Please refer to FIG. 5 together. FIG. 5 is a driving timing diagram of the liquid crystal unit 33 in Embodiment 1 of the present application. When the backlight module 10 emits red light and the scan line G1 is applied with a high level at the first time and the data line D1 is turned on, the liquid crystal cell P11 is turned on by applying a voltage and transmits the red light. When the scan line G2 is applied with a high level and the data line D1 is turned on at the second timing, the liquid crystal cell P21 is applied with a voltage to turn on and transmit the red light. When the scan line G3 is applied with the high level at the third timing and the data line D1 is turned on, the liquid crystal cell P31 is applied with voltage to turn on and transmit the red light. When the scan line G4 is applied with the high level at the fourth timing and the data line D1 is turned on, the liquid crystal cell P41 is turned on by applying a voltage and transmits the red light.

When the backlight module 10 emits green light and the scan line G1 is applied with a high level at the first time and the data line D1 is turned on, the liquid crystal cell P11 is applied with a voltage to turn on and transmit the green light. When the scan line G2 is applied with a high level at the second timing and the data line D1 is turned on, the liquid crystal cell P21 is applied with a voltage to turn on and transmit the green light. When the scan line G3 is applied with a high level at the third timing and the data line D1 is turned on, the liquid crystal cell P31 is applied with voltage to turn on and transmit the green light. When the scan line G4 is applied with a high level at the fourth time and the data line D1 is turned on, the liquid crystal cell P41 is turned on and transmits green light by applying a voltage.

When the backlight module 10 emits blue light and the scan line G1 is applied with a high level at the first time and the data line D1 is turned on, the liquid crystal cell P11 is turned on by applying a voltage and transmits the blue light. When the scan line G2 is applied with a high level at the second timing and the data line D1 is turned on, the liquid crystal cell P21 is applied with a voltage to turn on and transmit the blue light. When the scan line G3 is applied with a high level at the third time and the data line D1 is turned on, the liquid crystal cell P31 is applied with a voltage to turn on and transmit the blue light. When the scan line G4 is applied with the high level at the fourth timing and the data line D1 is turned on, the liquid crystal cell P41 is applied with a voltage to turn on and transmit the blue light.

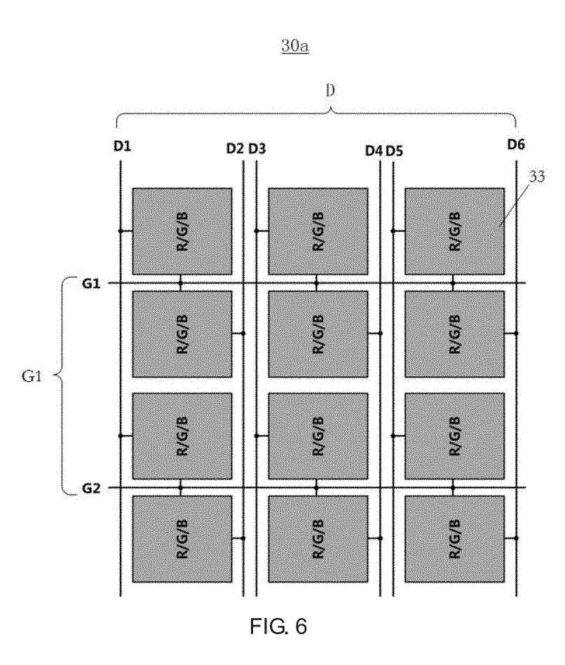

Please refer to FIG. 6. FIG. 6 is a schematic diagram of a liquid crystal panel of a liquid crystal display 100 in Embodiment 2 of the present application. The liquid crystal panel 30a in this embodiment is similar to the liquid crystal panel 30 in Embodiment 1 except that the scan lines of the liquid crystal panel 30a are n/2 rows, the data lines are 2 m columns, the liquid crystal cells 33 are n rows and m columns, each row of the scan lines G is connected to the corresponding two rows of liquid crystal cells 33 for outputting scan signals to gate the corresponding two rows of liquid crystal cells 33, each odd-numbered column of data lines D is connected to liquid crystal cells 33 corresponding to odd-numbered rows, and each even-numbered column of data lines D is connected to liquid crystal cells 33 corresponding to even-numbered rows for applying a driving voltage after the liquid crystal cells 33 are gated.

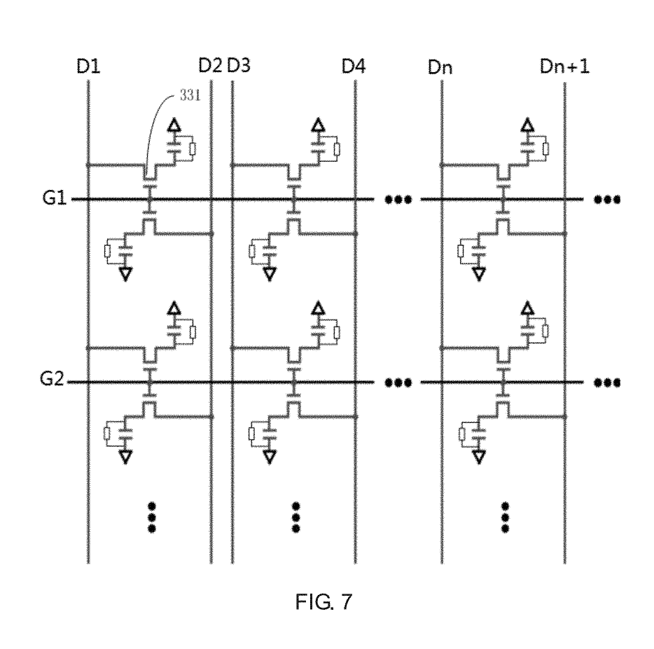

Please refer to FIG. 7 together. FIG. 7 is a schematic diagram of the driving circuit of the display in Embodiment 2 of the present application. The gates of the TFTs 331 of the liquid crystal cells 33 of every two rows are connected and are simultaneously connected to the same point on the scan lines G between the two liquid crystal cells 33.

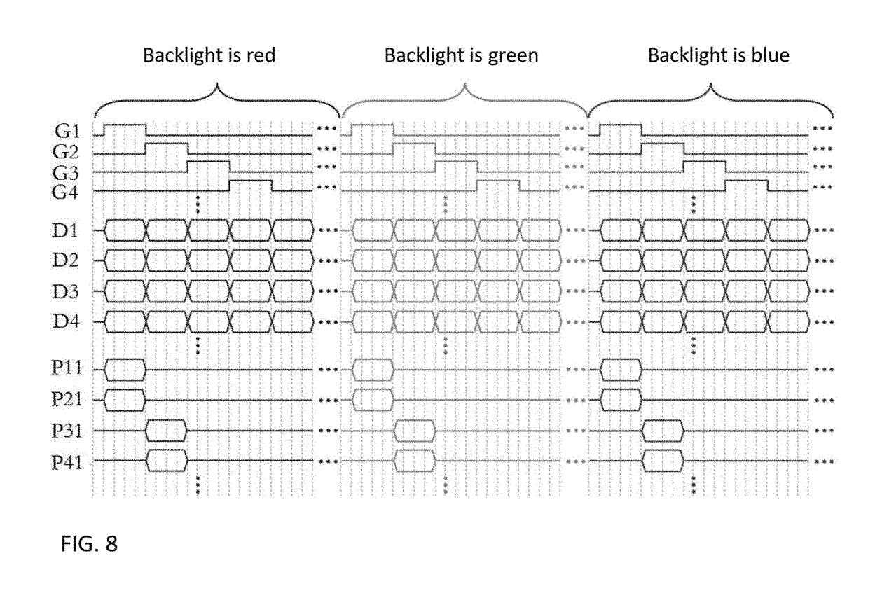

FIG. 8 is a driving timing diagram of a liquid crystal display in Embodiment 2 of the present application. When the backlight module 10 emits red light and the scan line G1 is applied with a high level at the first time and the data line D1 is turned on, the liquid crystal cells P11 and P21 are applied with a voltage to turn on and transmit the red light. When the scan line G2 is applied with a high level at the second timing and the data line D1 is turned on, the liquid crystal cells P31 and P41 are applied with voltage to turn on and transmit the red light.

When the backlight module 10 emits green light and the scan line G1 is applied with a high level at the first time and the data line D1 is turned on, the liquid crystal cells P11 and P21 are applied with a voltage to turn on and transmit the green light. When the scan line G2 is applied with a high level at the second timing and the data line D1 is turned on, the liquid crystal cells P31 and P41 are applied with voltage to turn on and transmit green light.

When the backlight module 10 emits blue light and the scan line G1 is applied with a high level at the first time and the data line D1 is turned on, the liquid crystal cells P11 and P21 are applied with a voltage to turn on and transmit the blue light. When the scan line G2 is applied with the high level at the second timing and the data line D1 is turned on, the liquid crystal cells P31 and P41 are applied with voltage to turn on and transmit the blue light.

The liquid crystal display module and the liquid crystal display having the liquid crystal display module of the present application, each liquid crystal cell can selectively transmit light of different colors emitted by the backlight module to visually synthesize the target color that the liquid crystal cell needs to display without disposing three sub-liquid crystal cells of red, green and blue for each liquid crystal cell, so that the filter layer is omitted, the transmittance is high, the pixel area is large, and the aperture ratio is high.

The above disclosure is only one preferred embodiment of the present application, and certainly can not be used to limit the scope of the present application. People of ordinary skill in the art may understand that all or part of the processes for implementing the foregoing embodiments, and equivalent changes made according to the claims of the present application, still fall within the scope of the present disclosure.

What is claimed is:

1. A liquid crystal display, comprising a liquid crystal panel and a backlight module, wherein the liquid crystal panel comprises a controller, a substrate, a plurality of scan lines disposed on the substrate, a plurality of data lines, and a plurality of liquid crystal cells, each of the liquid crystal cells is electrically connected to one of the scan lines and one of the data lines simultaneously, the backlight module sequentially emits three primary colors of light in each clock cycle, the controller controls the liquid crystal cells to selectively turn on according to a target color to be displayed by each of the liquid crystal cells to transmit a predetermined amount of light of a predetermined color for visually synthesizing the target color that the liquid crystal cells needs to display.

2. The liquid crystal display according to claim 1, wherein the backlight module comprises a three-primary-color laser source and a driving module, and the driving module drives the three-primary-color laser source to sequentially emit the three primary colors of light in each clock cycle.

3. The liquid crystal display according to claim 2, wherein each clock cycle is divided into three equal lengths to form a one-third cycle, a two-third cycle and a three-third cycle, the three-primary-color laser source comprises a red laser, a green laser and a blue laser, the driving module controls the red laser to emit red light of the three primary colors of light during the one-third cycle, controls the green laser to emit green light of the three primary colors of light during the third two-second period, and controls the blue laser to emit blue light of the three primary colors of light during the three-third cycle.

4. The liquid crystal display according to claim 1, wherein the controller determines a transmission amount of each of the three primary colors of light necessary for synthesizing the target color before controlling the liquid crystal cells to be turned on.

5. The liquid crystal display according to claim 4, wherein the controller respectively converts the transmission amount of each of the three primary colors of light necessary for synthesizing the target color into a corresponding transmission time, and controls the liquid crystal cells to continue being in a turn-on state the corresponding transmission times in an opened state when the backlight module emits the three primary colors of light.

6. The liquid crystal display according to claim 1, wherein the controller controls a voltage applied to the liquid crystal cells to control a turn-on degree of the liquid crystal cells to control a brightness of the target color transmitted by the liquid crystal cells.

7. The liquid crystal display according to claim 1, wherein the scan lines are n rows, the data lines are m columns, the liquid crystal cells are n rows and m columns, each row of the scan lines is connected to the liquid crystal cells of a corresponding row for outputting a scan signal to gate the liquid crystal cells of the corresponding row, each column of data lines is connected to the liquid crystal cells of a corresponding column for applying a driving voltage after the liquid crystal cells are gated.

8. The liquid crystal display according to claim 1, wherein the scan lines are n/2 rows, the data lines are 2 m columns, the liquid crystal cells are n rows and m columns, each row of the scan lines is connected to corresponding two rows of the liquid crystal cells for outputting a scan signal to gate the corresponding two rows of the liquid crystal cells, each odd-numbered column of the data lines is connected to the liquid crystal cells of a corresponding odd-numbered row, and each even-numbered column of the data lines is connected to the liquid crystal cells of a corresponding even-numbered row for applying a driving voltage after the liquid crystal cells are gated.

9. The liquid crystal display according to claim 1, wherein each of the liquid crystal cells comprises a TFT, a capacitor, a pixel electrode and a liquid crystal molecule unit, a gate of the TFT is electrically connected to a corresponding scan line, a drain of the TFT is electrically connected to a corresponding data line, a source of the TFT is electrically connected to one end of a corresponding capacitor, the other end of the capacitor is grounded, an end of the pixel electrode is connected in parallel with the capacitor, the other end of the pixel electrode is grounded, a plurality of the liquid crystal molecular units form a liquid crystal molecular layer, and the pixel electrode is located at one side of the liquid crystal molecular layer.
